(19) United States
(12) Patent Application Publication
(10) Pub. No.: US 2026/0371871 A1
(43) Pub. Date: Nov. 19, 2026

(54) Display Device

(71) Applicant: Samsung Display Co., Ltd., Yongin-si (KR)

(72) Inventors: Yeong Ho Kim, Yongin-si (KR); Kyeong Bin Min, Yongin-si (KR)

(73) Assignee: Samsung Display Co., Ltd., Yongin-si (KR)

(21) Appl. No.: 19/421,570

(22) Filed: Dec. 16, 2025

(30) Foreign Application Priority Data
May 14, 2025 (KR) 10-2025-0062275

(51) Int. Cl. H10K 59/131

(52) U.S. Cl. CPC H10K 59/131

(57) ABSTRACT

A display device is provided. The display device comprises a substrate including a display area and a non-display area; a display panel positioned on the substrate and including inspection pads that overlap the non-display area; and a driving circuit positioned on the display panel and including inspection bumps that overlap and are electrically connected to the inspection pads of the display panel, wherein the display panel further includes resistance measurement pads that are positioned on the substrate and overlap the non-display area, but do not overlap the driving circuit, and the resistance measurement pads are electrically connected to the inspection pads.

### CROSS-REFERENCE TO RELATED APPLICATION

This application claims priority to Korean Patent Application No. 10-2025-0062275 filed on May 14, 2025 in the Korean Intellectual Property Office, and all the benefits accruing therefrom under 35 U.S.C. 119. The contents of the foregoing application is incorporated herein by reference in its entirety.

### TECHNICAL FIELD

The present disclosure relates to a display device.

### BACKGROUND

A display device is a device that visually displays data. Such a display device includes a substrate partitioned into a display area and a non-display area. A plurality of pixels are arranged on the substrate in the display area, and a plurality of pads are arranged on the substrate in the non-display area. A driving circuit is coupled to the pads to deliver driving signals to the pixels. The driving circuit includes a plurality of bumps coupled to the pads, and the bumps may be bonded to separate pads.

### SUMMARY

One objective of the present disclosure is to provide a display device capable of precisely measuring contact resistance between pads of a display panel and bumps of a driving circuit prior to the subsequent process of connecting a circuit board, after bonding the display panel and the driving circuit.

The objectives of the present disclosure are not limited to those mentioned above, and other objectives not explicitly stated will be clearly understood by those skilled in the art based on the following description.

According to an aspect of the present disclosure, a display device comprises a substrate including a display area and a non-display area; a display panel positioned on the substrate and including inspection pads that overlap the non-display area; and a driving circuit positioned on the display panel and including inspection bumps that overlap and are electrically connected to the inspection pads of the display panel, wherein the display panel further includes resistance measurement pads that are positioned on the substrate and overlap the non-display area, but do not overlap the driving circuit, and the resistance measurement pads are electrically connected to the inspection pads.

In an aspect, the display device further comprises conductive balls arranged between the inspection pads of the display panel and the inspection bumps of the driving circuit, wherein the inspection pads and the inspection bumps are electrically connected by the conductive balls.

In an aspect, the inspection pads include at least three adjacent inspection pads, the resistance measurement pads include at least four adjacent resistance measurement pads, and the at least four adjacent resistance measurement pads and the at least three adjacent inspection pads are electrically connected such that at least one of the at least four adjacent resistance measurement pads corresponds to at least one of the at least three adjacent inspection pads.

In an aspect, the at least three adjacent inspection pads are arranged side by side in a first direction.

In an aspect, the at least three adjacent inspection pads are arranged side by side in a second direction intersecting the first direction.

In an aspect, the at least three adjacent inspection pads are arranged in both the first direction and a second direction intersecting the first direction.

In an aspect, the at least four adjacent resistance measurement pads are respectively a ground pad, a first voltage pad, a second voltage pad, and a current pad.

In an aspect, the display panel further includes a plurality of signal pads that are positioned on the substrate, overlap the non-display area, and are arranged in a first direction and a second direction intersecting the first direction, the driving circuit further includes a plurality of signal bumps that overlap and are electrically connected to the plurality of signal pads, respectively, and the inspection pads are arranged outside the plurality of signal pads in the first direction.

In an aspect, the display device further comprises conductive balls arranged between the plurality of signal pads of the display panel and the plurality of signal bumps of the driving circuit, wherein the plurality of signal pads and the plurality of signal bumps are electrically connected by the conductive balls.

In an aspect, the inspection pads are electrically isolated from the plurality of signal pads.

In an aspect, the plurality of signal pads include a plurality of first signal pads arranged along the first and second directions, and a plurality of second signal pads positioned outside the first signal pads in the second direction and arranged along the first direction, and the plurality of first signal pads and the plurality of second signal pads are input pads and output pads, respectively, for outputting signals to or receiving signals from the driving circuit.

In an aspect, the inspection pads include a plurality of first inspection pads positioned outside the plurality of first signal pads in the first direction, and a plurality of second inspection pads positioned outside the plurality of second signal pads in the first direction.

In an aspect, the plurality of first inspection pads include at least three adjacent first inspection pads, the resistance measurement pads include at least four adjacent first resistance measurement pads, and the at least four adjacent first resistance measurement pads and the at least three adjacent first inspection pads are electrically connected such that at least one of the at least four adjacent first resistance measurement pads corresponds to at least one of the at least three adjacent first inspection pads.

In an aspect, the at least four adjacent first resistance measurement pads are respectively a ground pad, a first voltage pad, a second voltage pad, and a current pad.

In an aspect, the plurality of second inspection pads include at least three adjacent second inspection pads, the resistance measurement pads include at least four adjacent second resistance measurement pads, and the at least four adjacent second resistance measurement pads and the at least three adjacent second inspection pads are electrically connected such that at least one of the at least four adjacent second resistance measurement pads corresponds to at least one of the at least three adjacent second inspection pads.

In an aspect, the at least four adjacent second resistance measurement pads are respectively a ground pad, a first voltage pad, a second voltage pad, and a current pad.

In an aspect, the plurality of first inspection pads are arranged side by side in the first direction, and the plurality of second inspection pads are arranged side by side in the first direction.

In an aspect, the plurality of first inspection pads are arranged side by side in the second direction, and the plurality of second inspection pads are arranged side by side in the first direction.

In an aspect, the plurality of first inspection pads are arranged in the first and second directions, and the plurality of second inspection pads are arranged side by side in the first direction.

According to the an aspect of the present disclosure, an electronic device comprises a display device for displaying an image; and a processor configured to transmit an image data signal to the display device to display the image, wherein the display device comprises: a substrate including a display area and a non-display area; a display panel positioned on the substrate and including inspection pads that overlap the non-display area; and a driving circuit positioned on the display panel and including inspection bumps that overlap and are electrically connected to the inspection pads of the display panel, the display panel further includes resistance measurement pads that are positioned on the substrate and overlap the non-display area, but do not overlap the driving circuit, and the resistance measurement pads are electrically connected to the inspection pads.

According to the aforementioned and other aspects of the present disclosure, a display device includes a resistance measurement pad in a dummy area of a display panel, so that contact resistance between a pad of the display panel and a bump of a driving circuit can be precisely measured before a subsequent process is performed after bonding the display panel and the driving circuit during the manufacturing process of the display device, thereby providing a display device capable of minimizing the defect rate of the display device.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing aspects thereof in detail with reference to the attached drawings, in which:

FIG. 1 is a plan view of a display device according to an aspect;

FIG. 2 is a plan view of the display device of FIG. 1, with a driving circuit, a first circuit board, and a second circuit board removed;

FIG. 3 is an enlarged plan view of a first pad area of FIG. 2;

FIG. 4 is a plan view for explaining connections between resistance measurement pads and inspection pads of the display device, according to an aspect;

FIG. 5 is a cross-sectional view taken along line X1–X1’ of FIG. 4;

FIG. 6 is a circuit diagram for explaining an equivalent circuit of an inspection pad of FIG. 5;

FIG. 7 is a circuit diagram for explaining a four-terminal resistance measurement of the equivalent circuit of FIG. 6;

FIGS. 8 through 10 are plan views for explaining connections between resistance measurement pads and inspection pads of the display device, according to other aspects;

FIG. 11 is a block diagram of an electronic device according to an aspect; and

FIG. 12 is a schematic view of an electronic device according to various aspects.

### DETAILED DESCRIPTION

The present disclosure will now be described more fully hereinafter with reference to the accompanying drawings, in which preferred aspects of the disclosure are shown. This disclosure may, however, be embodied in different aspects and should not be construed as limited to the aspects set forth herein. Rather, these aspects are provided so that this disclosure will be thorough and complete, and will fully convey the scope of the disclosure to those skilled in the art.

It will also be understood that when a layer is referred to as being "on" another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various aspects of the present disclosure may be combined or combined with each other, in part or in whole, and technically various interlocking and driving are possible. Each aspect may be implemented independently of each other or may be implemented together in an association.

Hereinafter, aspects of the present disclosure will be described in detail with reference to the accompanying drawings.

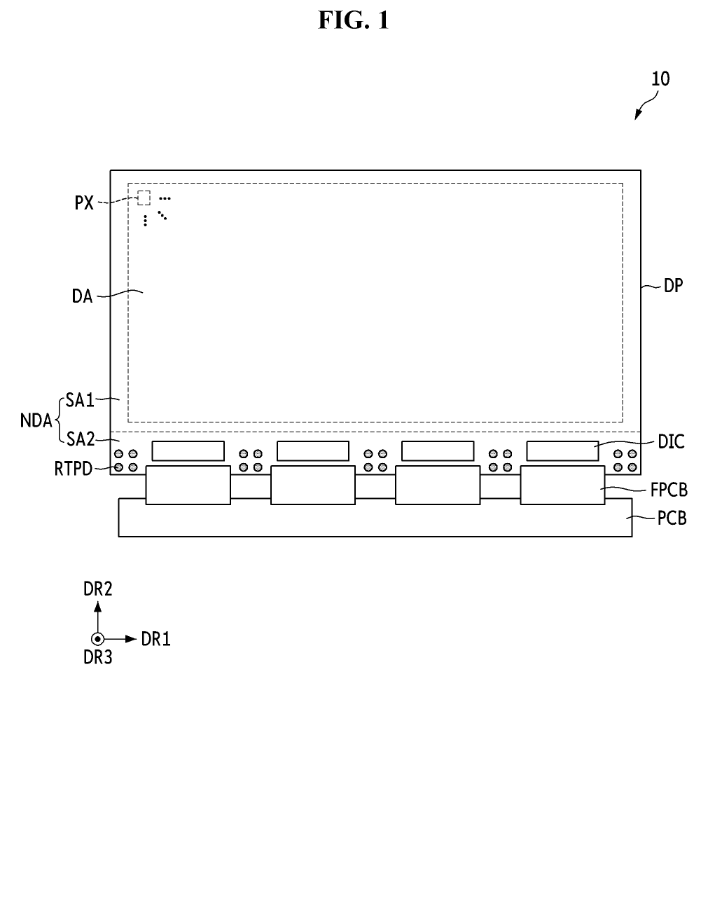

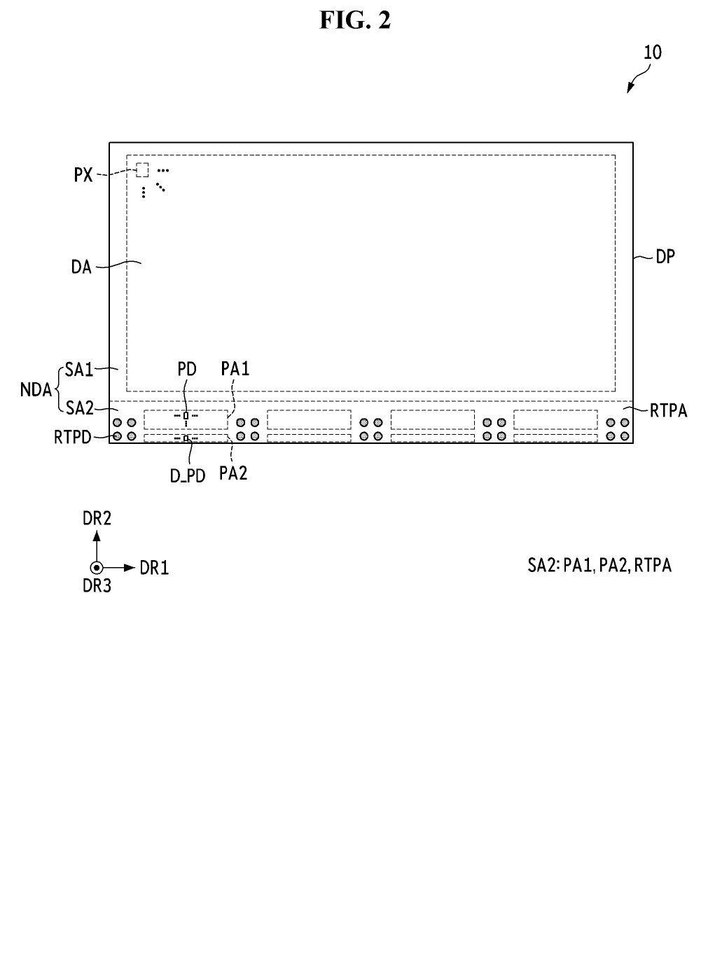

FIG. 1 is a plan view of a display device according to an aspect. FIG. 2 is a plan view of the display device of FIG. 1, with a driving circuit, a first circuit board, and a second circuit board removed.

Referring to FIGS. 1 and 2, a display device 10, which is a device that displays moving or still images, may be used as a display screen for various products.

The display device 10 may be a light-emitting display device such as an organic light emitting display device including an organic light-emitting diode, a quantum-dot light-emitting display device including a quantum-dot light-emitting layer, an inorganic light-emitting display device including an inorganic semiconductor, or an ultra-small light-emitting display device including an ultra-small light-emitting diode such as a micro- or nano-light-emitting diode (micro-LED or nano-LED), but is not limited thereto. For example, the display device 10 may be a display device of a type other than a light-emitting display device. Aspects will hereinafter be described in which the display device 10 is a light-emitting display device (e.g., an organic light-emitting display device).

The shape of the display device 10 may vary. For example, the display device 10 may have a vertically elongated rectangle, a horizontally elongated rectangle, a square, a rectangle with rounded corners (or vertices), another polygonal shape, or a circular shape. In FIGS. 1 and 2, the display device 10 is illustrated as having a rectangular shape elongated in a first direction DR1.

In the present disclosure, the first direction DR1 may be a direction on the plane parallel to the longitudinal sides of the display device 10, for example, the horizontal direction of the display device 10. A second direction DR2 may be a direction on the plane parallel to the short sides of the display device 10, for example, the vertical direction of the display device 10. A third direction DR3 may be a thickness direction of the display device 10.

The display device 10 may include a display panel DP for displaying an image, and driving circuits DIC and first circuit boards FPCB connected to the display panel DP. The display device 10 may further include a second circuit board PCB connected to first circuit boards FPCB.

The display panel DP may be provided as a rigid panel that is substantially not deformable or may be provided as a flexible panel that is at least partially deformable such as foldable, bendable, or rollable. The display panel DP may be provided to the display device 10 in an unbent state or in a bent state in some areas.

The display panel DP may include a display area DA and a non-display area NDA.

A plurality of pixels PX may be arranged in the display area DA. The pixels PX may display an image. Each of the pixels PX may include a pixel driving circuit that includes transistors (e.g., a switching transistor, a driving transistor, etc.) and at least one capacitor, and a light-emitting element electrically connected to the pixel driving circuit. The pixels PX may generate light in response to electrical signals applied thereto and may display an image through the display area DA. In some aspects, some of the pixels PX may include transistors arranged in the non-display area NDA, but are not limited thereto. The display area DA may have various shapes. For example, the display area DA may have a rectangular shape, a non-rectangular polygonal shape, a circular shape, an elliptical shape, an irregular shape, or another shape. In one aspect, the display area DA may have a shape corresponding to the shape of the display panel DP.

The non-display area NDA may be positioned around the display area DA. The non-display area NDA may include a first peripheral area SA1 surrounding the display area DA, and a second peripheral area SA2 protruding downward from the first peripheral area SA1.

The second peripheral area SA2 may include first pad areas PA1 in which the driving circuits DIC are arranged, second pad areas PA2 in which the first circuit boards FPCB are arranged, and inspection pad area RTPA in which inspection pads RTPD are arranged.

The first pad areas PA1 may be positioned adjacent to the display area DA within the second peripheral area SA2. The driving circuits DIC may be connected to the first pad areas PA1, and may be provided as driving chips. Signal pads PD connected to the driving circuits DIC may be arranged in the first pad areas PA1.

The second pad areas PA2 may be located farther from the display area DA than the first pad areas PA1 within the second peripheral area SA2. The first circuit boards FPCB may be connected to the second pad areas PA2. Display pads D_PD connected to the first circuit boards FPCB may be arranged in the second pad areas PA2. The display pads D_PD may be panel input pads that receive signals from the first circuit boards FPCB.

The inspection pad area RTPA may be located around the first pad areas PA1 and the second pad areas PA2 within the second peripheral area SA2. For example, as depicted in FIG. 2, the inspection pad area RTPA may be an area located outside the first pad areas PA1 and the second pad areas PA2. The inspection pad area RTPA may be a dummy area of the display panel DP that does not overlap the first pad areas PA1 connected to the driving circuits DIC or the second pad areas PA2 connected to the first circuit boards FPCB in the second peripheral area SA2.

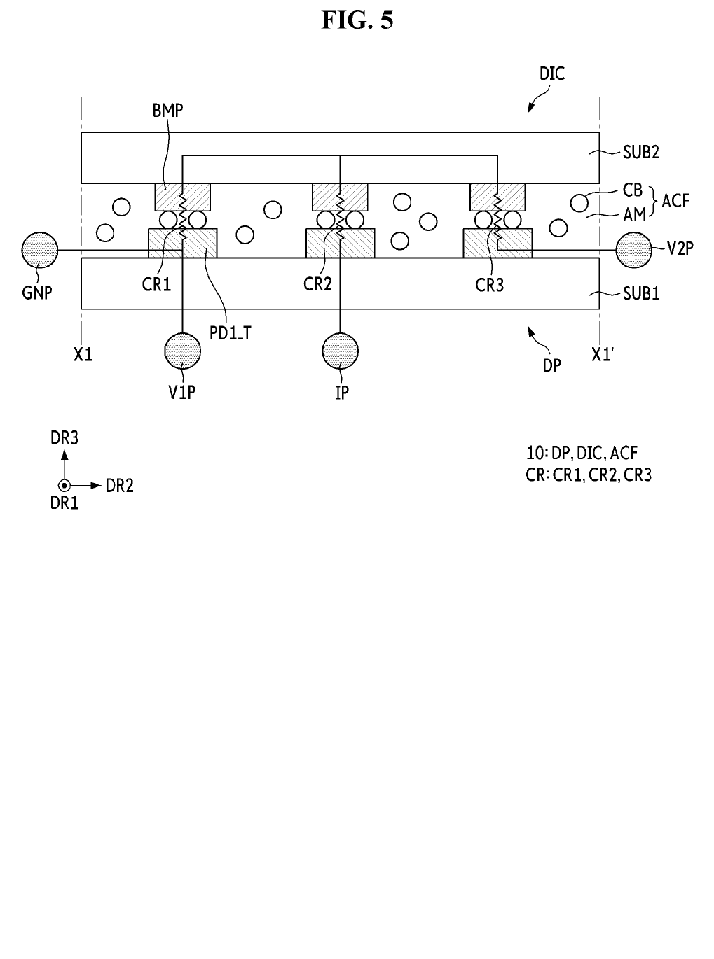

Resistance measurement pads RTPD, which are connected to the signal pads PD in the first pad areas PA1, may be arranged in the inspection pad area RTPA. The resistance measurement pads RTPD may be test pads for measuring contact resistances (CR in FIG. 5) between the signal pads (PD in FIG. 5) and bumps (BMP in FIG. 5) of each of the driving circuits DIC, which will be described later.

The first circuit boards FPCB may be connected to the display panel DP and the second circuit board PCB. For example, first sides of the first circuit board FPCB may be electrically connected to the non-display area NDA of the display panel DP, and second sides of the first circuit boards FPCB may be electrically connected to the second circuit board PCB. The first circuit boards FPCB may be flexible films such as flexible printed circuit boards or printed circuit boards, but are not limited thereto. For example, the first circuit boards FPCB may be flexible printed circuit boards.

The second circuit board PCB may be electrically connected to the display panel DP through the first circuit boards FPCB and may exchange signals with the driving circuits DIC. The second circuit board PCB may supply image data, control signals, and power voltages to the display panel DP or the first circuit boards FPCB. Active elements and passive elements may be arranged on the second circuit board PCB. For example, a timing controller and a power supply unit may be arranged on the second circuit board PCB. The second circuit board PCB may be a flexible printed circuit board or a rigid printed circuit board, but is not limited thereto. For example, the second circuit board PCB may be a rigid printed circuit board.

The power supply unit may supply power voltages to the pixels PX, a gate driver, an emission driver, and the data driving circuits DIC. The timing controller may control operations of the gate driver, the emission driver, and the driving circuits DIC.

Through the first circuit boards FPCB, a gate timing control signal, a light-emitting timing control signal, a gate clock signal, a light-emitting clock signal, a gate start signal, a light-emitting start signal, a high-potential voltage, and a low-potential voltage from the timing controller positioned on the second circuit board PCB may be supplied to the gate driver and the emission driver. For example, the gate timing control signal, gate clock signal, gate start signal, high-potential voltage, and low-potential voltage may be supplied to the gate driver, and the light-emitting timing control signal, light-emitting clock signal, light-emitting start signal, high-potential voltage, and low-potential voltage may be supplied to the emission driver. In addition, through the first circuit boards FPCB, power signals from the power supply unit positioned on the second circuit board PCB may be supplied to the gate driver, the emission driver, and the pixels PX. The power signals may include, for example, a driving voltage, a common voltage, an initialization voltage, and a bias voltage.

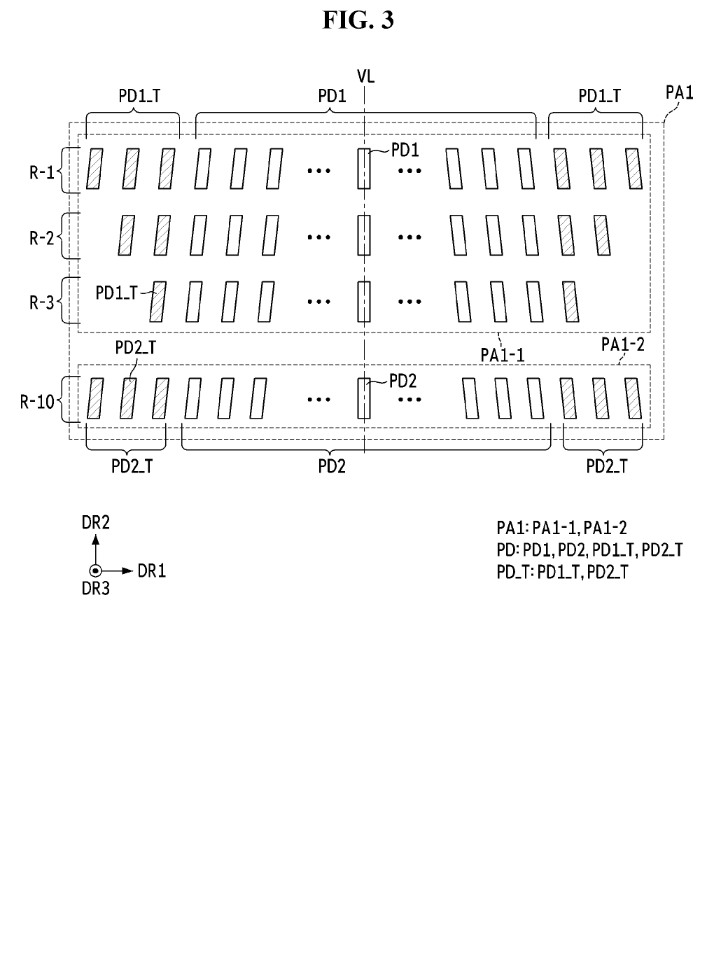

FIG. 3 is an enlarged plan view of a first pad area of FIG. 2.

Referring to FIG. 3, signal pads PD arranged in a first pad area PA1 may include first signal pads PD1 and second signal pads PD2. The first signal pads PD1 may be input pads that receive signals from a driving circuit DIC, and the region in the first pad area PA1 in which the first signal pads PD1 are arranged may be defined as a first sub-pad area PA1-1. The second signal pads PD2 may be output pads that output signals to the driving circuit DIC, and the region in the first pad area PA1 in which the second signal pads PD2 are arranged may be defined as a second sub-pad area PA1-2.

The first signal pads PD1 may be arranged in the first sub-pad area PA1-1 along the first and second directions DR1 and DR2. Rows of first signal pads PD1 arranged along the first direction DR1 may be defined as input pad rows. FIG. 3 illustrates three input pad rows, i.e., first, second, and third input pad rows R-1, R-2, and R-3, as being arranged along the second direction DR2. The arrangement of the first signal pads PD1 is not particularly limited as long as at least two or more input pad rows are arranged along the second direction DR2.

The second signal pads PD2 may be arranged in the second sub-pad area PA1-2 along the first direction DR1. The second signal pads PD2 may be arranged in a single pad row, and the single pad row may be defined as an output pad row R-10. However, the arrangement of the second signal pads PD2 is not particularly limited.

First central pads, which are first signal pads PD1 positioned at the center, in the first direction DR1, of the first pad area PA1, may be arranged on a reference line VL. The first central pads PD1 may extend along the second direction DR2. First signal pads PD1 positioned to the left or right of the reference line VL may extend to have a predetermined inclination with respect to the reference line VL. The first signal pads PD1 positioned to the left of the reference line VL may extend to form an acute angle in a clockwise direction with respect to the reference line VL. The first signal pads PD1 positioned to the right of the reference line VL may extend to form an acute angle in a counterclockwise direction with respect to the reference line VL.

A second central pad, which is a second signal pad PD2 positioned at the center, in the first direction DR1, of the first pad area PA1, may be arranged on the reference line VL. The second central pad may extend along the second direction DR2. Second signal pads PD2 positioned to the left or right of the reference line VL may extend to have a predetermined inclination with respect to the reference line VL. Some second signal pads PD2 positioned to the left of the reference line VL may extend to form an acute angle in the clockwise direction with respect to the reference line VL, and some second signal pads PD2 positioned to the right of the reference line VL may extend to form an acute angle in the counterclockwise direction with respect to the reference line VL.

The signal pads PD may further include inspection pads PD_T arranged in the first pad area PA1. The inspection pads PD_T may include first inspection pads PD1_T arranged in the first sub-pad area PA1-1 and second inspection pads PD2_T arranged in the second sub-pad area PA1-2. The inspection pads PD_T may be pads electrically isolated from the first signal pads PD1 and the second signal pads PD2 to measure the contact resistances CR with bumps BMP of the driving circuit DIC, and may be arranged to supplement the areas between the edges of the first pad area PA1 and the first signal pads PD1 and second signal pads PD2. The first inspection pads PD1_T may be arranged outward of the outermost first signal pads PD1 in at least one of the first, second, and third input pad rows R-1, R-2, and R-3. The second inspection pads PD2_T may be arranged outward of the outermost second signal pads PD2 in the output pad row R-10. The first inspection pads PD1_T may be arranged adjacent to the left or right side of the first sub-pad area PA1-1, and the second inspection pads PD2_T may be arranged adjacent to the left or right side of the second sub-pad area PA1-2. FIG. 3 illustrates the first inspection pads PD1_T as being arranged outside the first, second, and third input pad rows R-1, R-2, and R-3 and the second inspection pads PD2_T as being arranged outside the output pad row R-10, but the arrangement of the inspection pads PD_T is not limited thereto. The inspection pads PD_T may extend in a direction parallel to the extension direction of adjacent first signal pads PD1 and second signal pads PD2. Inspection pads PD_T arranged adjacent to each pad row may be arranged in parallel with first signal pads PD1 in a corresponding pad row along the first direction DR1.

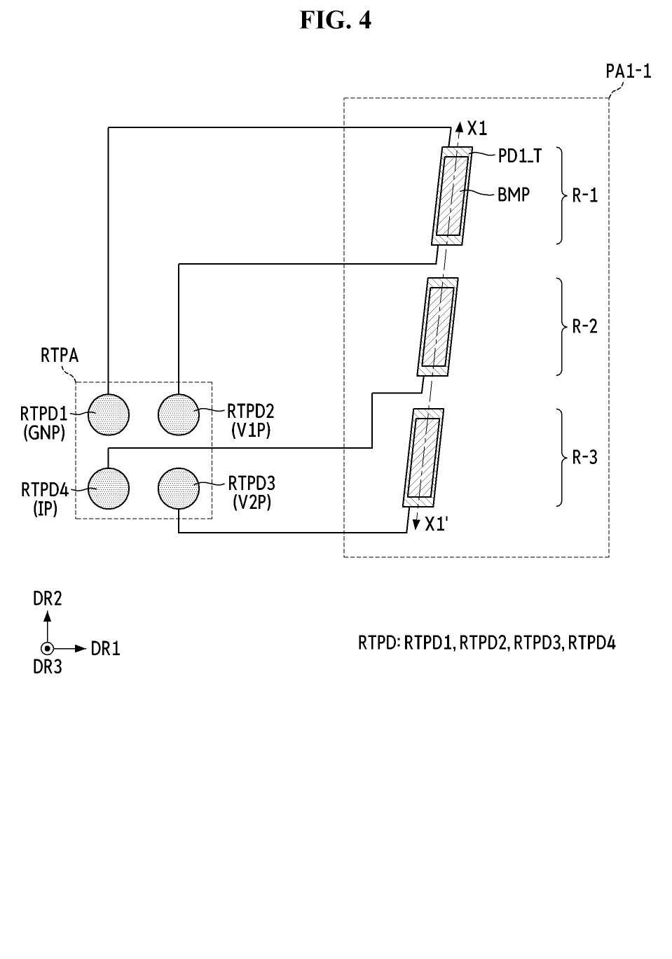

For convenience of description, the arrangement of, for example, the first inspection pads PD1_T, has been described so far, but the second inspection pads PD2_T, the first signal pads PD1, and the second signal pads PD2 may have the same arrangement structure as that between the first inspection pads PD1_T and the bumps BMP of the driving circuit DIC, as will hereinafter be described with reference to FIGS. 4 and 5, but are not limited thereto.

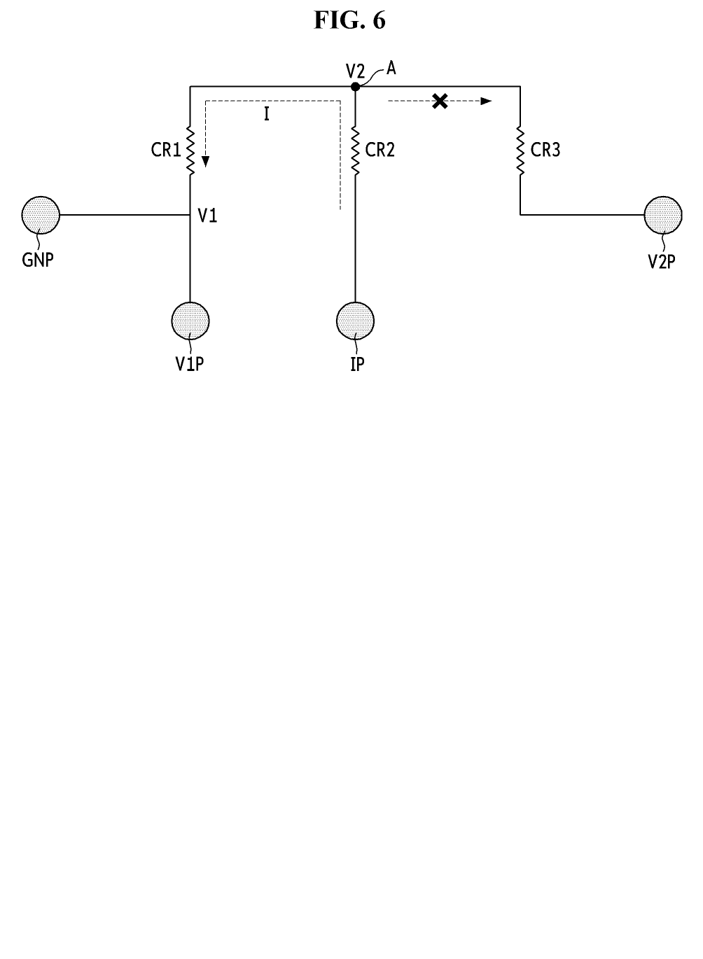

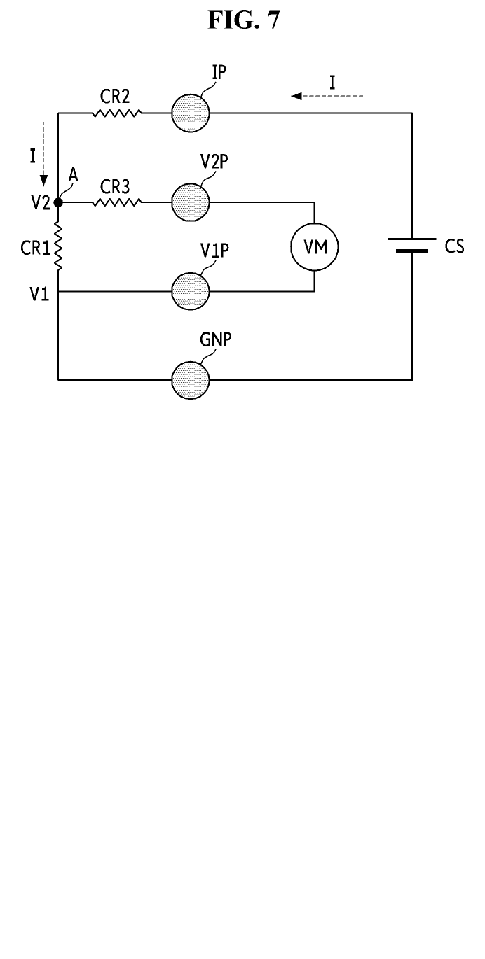

FIG. 4 is a plan view for explaining connections between resistance measurement pads and inspection pads of the display device, according to an aspect. FIG. 5 is a cross-sectional view taken along line X1–X1’ of FIG. 4. FIG. 6 is a circuit diagram for explaining an equivalent circuit of an inspection pad of FIG. 5. FIG. 7 is a circuit diagram for explaining a four-terminal resistance measurement of the equivalent circuit of FIG. 6.

Referring to FIG. 4, first inspection pads PD1_T arranged in a first sub-pad area PA1-1 may be electrically connected to the resistance measurement pads RTPD arranged in the resistance measurement pad area RTPA.

Specifically, the resistance measurement pads RTPD may include at least four adjacent resistance measurement pads RTPD for measuring the contact resistances CR between the inspection pads PD_T of the display panel DP and the bumps BMP of the driving circuit DIC. The resistance measurement pads RTPD may be electrically connected to at least three adjacent first inspection pads PD1_T such that each first inspection pads PD1_T is electrically connected to at least one corresponding resistance measurement pad RTPD and each resistance measurement pad RTPD is electrically connected to at least one corresponding first inspection pads PD1_T. For example, as illustrated in FIG. 4, the resistance measurement pads RTPD may include adjacent first, second, third, and fourth resistance measurement pads RTPD1, RTPD2, RTPD3, and RTPD4. Among three first inspection pads PD1_T arranged along the second direction DR2, a first inspection pad PD1_T arranged in the first input pad row R-1 may be connected to the first and second resistance measurement pads RTPD1 and RTPD2, a first inspection pad PD1_T arranged in the second input pad row R-2 may be connected to the fourth resistance measurement pad RTPD4, and a first inspection pad PD1_T arranged in the third input pad row R-3 may be connected to the third resistance measurement pad RTPD3.

The first, second, third, and fourth resistance measurement pads RTPD1, RTPD2, RTPD3, and RTPD4, which are connected to the first inspection pads PD1_T, may include a ground pad GNP, a first voltage pad V1P, a second voltage pad V2P, and a current pad IP for applying voltage and current in a four-terminal resistance measurement.

In FIG. 4, the first, second, third, and fourth resistance measurement pads RTPD1, RTPD2, RTPD3, and RTPD4 are illustrated as being the ground pad GNP, the first voltage pad V1P, the second voltage pad V2P, and the current pad IP, respectively, but are not limited thereto. That is, the ground pad GNP, first voltage pad V1P, second voltage pad V2P, and current pad IP may be appropriately selected from among the first, second, third, and fourth resistance measurement pads RTPD1, RTPD2, RTPD3, and RTPD4 as needed. Accordingly, the electrical connections between the resistance measurement pads RTPD and the first inspection pads PD1_T may be adjusted.

In one aspect, the first, second, third, and fourth resistance measurement pads RTPD1, RTPD2, RTPD3, and RTPD4 may be sequentially arranged side by side clockwise in the first and second directions DR1 and DR2, but the arrangement of the first, second, third, and fourth resistance measurement pads RTPD1, RTPD2, RTPD3, and RTPD4 is not limited thereto. That is, the first, second, third, and fourth resistance measurement pads RTPD1, RTPD2, RTPD3, and RTPD4 may be appropriately arranged in various manners within the resistance measurement pad area RTPA as needed.

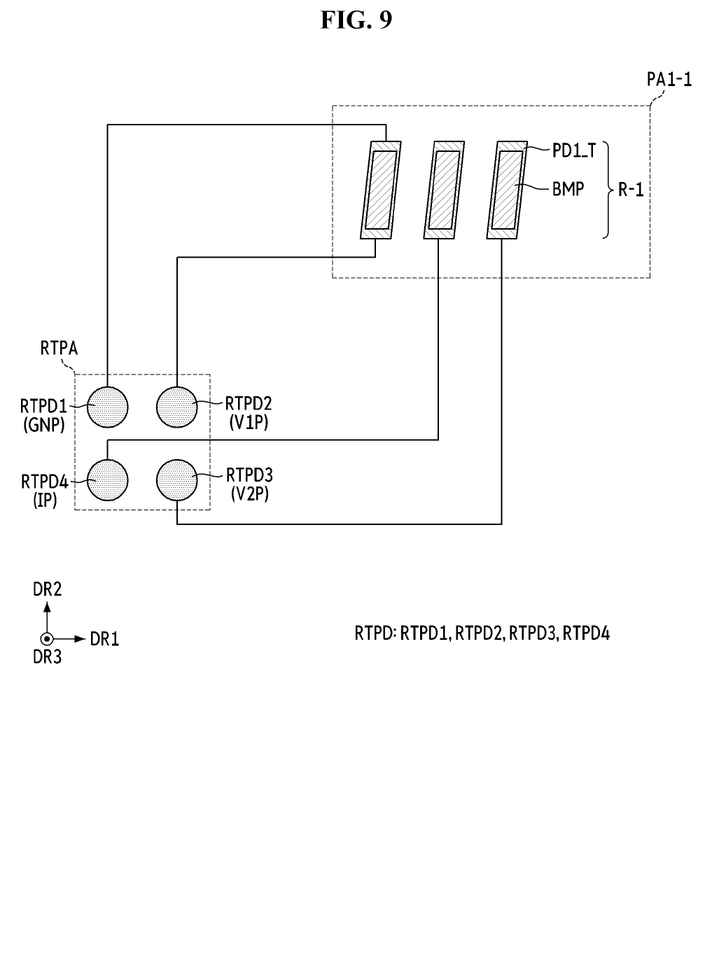

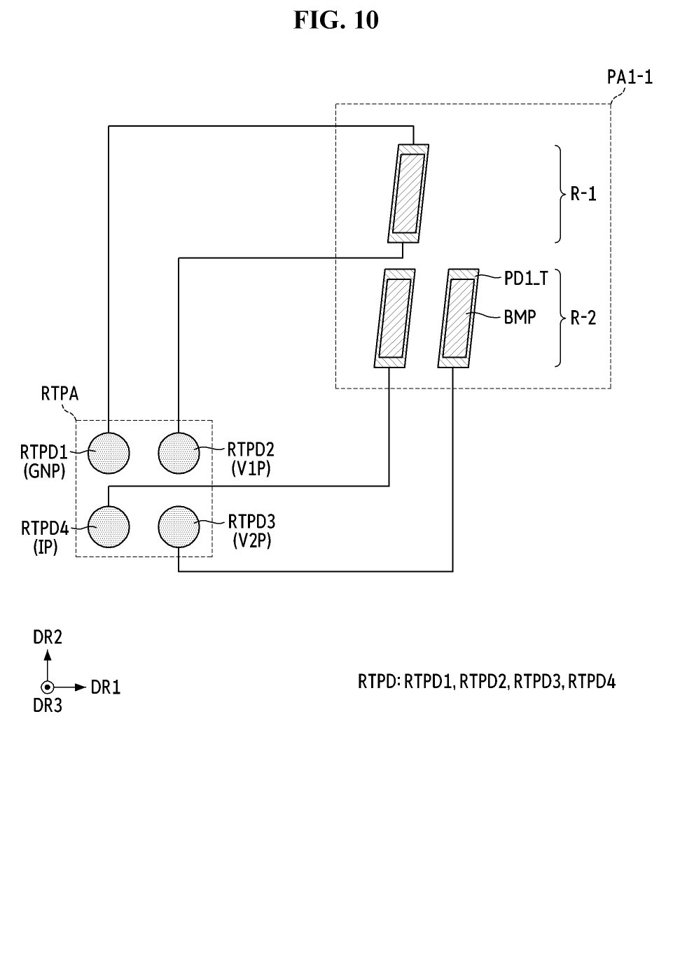

Also, in one aspect, three first inspection pads PD1_T arranged side by side along the second direction DR2 in the first sub-pad area PA1-1 may be connected to the first, second, third, and fourth resistance measurement pads RTPD1, RTPD2, RTPD3, and RTPD4, but the present disclosure is not limited thereto. The arrangement of the first inspection pads PD1_T connected to the resistance measurement pads RTPD may vary and is not particularly limited. Other aspects of the arrangement of the first inspection pads PD1_T will be described later with reference to FIGS. 9 and 10.

Referring to FIG. 5, the display device 10 may include the display panel DP, a driving circuit DIC arranged on the display panel DP, and an adhesive film ACF positioned between the display panel DP and the driving circuit DIC.

The display panel DP may include a first substrate SUB1 and signal pads PD.

The first substrate SUB1 may be a base member that supports the layers of the display panel DP. In some aspects, the first substrate SUB1 may be a rigid substrate and may include a glass material or a metal material. Alternatively, in some aspects, the first substrate SUB1 may be a flexible substrate that is bendable, foldable, or rollable, and may include a polymer resin such as polyimide (PI), but is not limited thereto.

The signal pads PD may be positioned on the first substrate SUB1. The signal pads PD may be arranged on the first substrate SUB1 along the first and second directions DR1 and DR2. In FIG. 5, the first inspection pads PD1_T are illustrated as, for example, being arranged in the first sub-pad area PA1-1 along the second direction DR2.

The driving circuit DIC may include a second substrate SUB2 and bumps BMP.

The second substrate SUB2 may be a base member that supports the layers of the driving circuit DIC. In some aspects, the second substrate SUB2 may be a rigid substrate and may include a glass material or a metal material. Alternatively, in some aspects, the second substrate SUB2 may be a flexible substrate that is bendable, foldable, or rollable, and may include a polymer resin such as PI, but is not limited thereto.

The bumps BMP may be positioned on the second substrate SUB2. The bumps BMP may be arranged to correspond to the signal pads PD of the display panel DP, and may include output bumps for outputting signals to the signal pads PD and input bumps for receiving signals from the signal pads PD. FIGS. 4 and 5 illustrate the bumps BMP as, for example, being arranged to correspond to the first inspection pads PD1_T.

Short wirings may be formed inside the driving circuit DIC, and may electrically connect the signal pads PD and the bumps BMP arranged in the first and second directions DR1 and DR2. For example, as illustrated in FIG. 5, the first inspection pads PD1_T and the bumps BMP arranged along the second direction DR2 may be electrically connected by the short wirings in the second substrate SUB2.

The adhesive film ACF may be an anisotropic conductive film with conductivity and may include conductive balls CB and an adhesive member AM.

Each of the conductive balls CB may be a conductive fine particle. For example, the conductive balls CB may include conductive particles such as particles of a metal or metal oxide. The metal may include nickel (Ni), iron (Fe), copper (Cu), aluminum (Al), tin (Sn), zinc (Zn), chromium (Cr), cobalt (Co), silver (Ag), and gold (Au).

The adhesive member AM may include a polymer material. For example, an epoxy resin, or an acrylic resin may be used as the adhesive member AM.

The signal pads PD of the display panel DP and the bumps BMP of the driving circuit DIC may be electrically connected via the conductive balls CB of the adhesive film ACF. For example, as illustrated in FIG. 5, the first inspection pads PD1_T and the bumps BMP may be electrically connected via the conductive balls CB, and each of the first inspection pads PD1_T and the bumps BMP may have a contact resistance CR due to the conductive balls CB interposed therebetween. For example, as illustrated in FIG. 5, the first inspection pads PD1_T of the display panel DP, arranged along the second direction DR2, may be connected to the bumps BMP of the driving circuit DIC via the conductive balls CB and may thereby have respective contact resistances CR, i.e., first, second, and third contact resistances CR1, CR2, and CR3.

Referring to FIGS. 5, 6, and 7, a test current I supplied from a current source CS to the current pad IP may flow to the ground pad GNP and the first voltage pad V1P. At this time, a voltage V2 applied to the second voltage pad V2P may be higher than a voltage V1 applied to the first voltage pad V1P. Thus, the test current I may not flow to the second voltage pad V2P, and a potential difference between a node A and the second voltage pad V2P may become zero. Accordingly, since a potential difference generated by a first contact resistance CR1 may be measured by a voltmeter VM connected to the first and second voltage pads V1P and V2P the first contact resistance CR1 may be accurately measured. In this manner, the contact resistances CR between the first inspection pads PD1_T and the bumps BMP, connected via the conductive balls CB from the resistance measurement pads RTPD arranged in parts of the resistance measurement pad area RTPA that do not overlap the driving circuit DIC and a first circuit board FPCB, may be measured. As a result, during the manufacture of the display device 10, connection failure between the driving circuits DIC and the display panel DP may be directly identified before a subsequent process of connecting the first circuit boards FPCB and the second circuit board PCB is performed, thereby minimizing the defect rate of the display device 10.

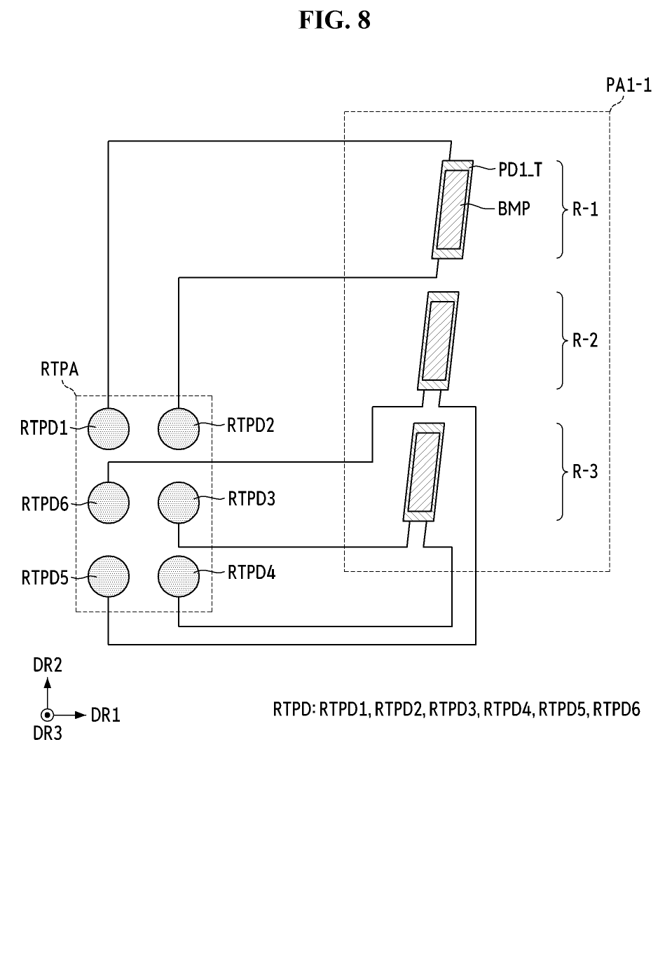

FIGS. 8 through 10 are plan views for explaining connections between resistance measurement pads and inspection pads of the display device, according to other aspects.

The following description focuses on differences, and redundant descriptions will be omitted.

Referring to FIG. 8, alternatively to what is illustrated in FIG. 4, the resistance measurement pads RTPD may include first through sixth resistance measurement pads RTPD1 through RTPD6, which are electrically connected such each one of three adjacent first inspection pads PD1_T is connected to two of corresponding resistance measurement pads RTPD. Accordingly, four of the first through sixth resistance measurement pads RTPD1 through RTPD6 may be selected as a ground pad GNP, a first voltage pad V1P, a second voltage pad V2P, and a current pad IP for applying voltage and current in a four-terminal resistance measurement. For example, if the third and fourth resistance measurement pads RTPD3 and RTPD4 are selected as the ground pad GNP and the first voltage pad V1P, respectively, the first or second resistance measurement pad RTPD1 or RTPD2 is selected as the second voltage pad V2P, and the fifth or sixth resistance measurement pad RTPD5 or RTPD6 is selected as the current pad IP, then the third contact resistance CR3 may be identified through a four-terminal resistance measurement.

In this case, the first, second, and third contact resistances CR1, CR2, and CR3 between the three adjacent first inspection pads PD1_T and the bumps BMP may be accurately measured. Therefore, during the manufacture of the display device 10, connection failure between the driving circuits DIC and the display panel DP may be immediately detected prior to the subsequent process of connecting the first circuit boards FPCB and the second circuit board PCB, thereby minimizing the defect rate of the display device 10.

Referring to FIG. 9, alternatively to what is illustrated in FIG. 4, at least three first inspection pads PD1_T, connected to at least four adjacent resistance measurement pads RTPD, may be arranged side by side along the first direction DR1 as the first inspection pads PD1_T. For example, as illustrated in FIG. 9, first inspection pads PD1_T arranged side by side along the first direction DR1 in a first input pad row R-1 in a first sub-pad area PA1-1 may be electrically connected to first through fourth resistance measurement pads RTPD1 through RTPD4 arranged in the resistance measurement pad area RTPA.

FIG. 9 illustrates first inspection pads PD1_T arranged in the first sub-pad area PA1-1 as an example, but second inspection pads PD2_T arranged in a second sub-pad area PA1-2 may have the same arrangement structure as the first inspection pads PD1_T. Accordingly, contact resistances CR between the second inspection pads PD2_T and bumps BMP of a driving circuit DIC may be accurately measured. Therefore, during the manufacture of the display device 10, connection failure between the driving circuits DIC and the display panel DP may be immediately detected prior to the subsequent process of connecting the first circuit boards FPCB and the second circuit board PCB, thereby minimizing the defect rate of the display device 10.

Referring to FIG. 10, alternatively to what is illustrated in FIG. 4, at least three first inspection pads PD1_T connected to at least four adjacent resistance measurement pads RTPD may be arranged side by side along the first or second direction DR1 or DR2 as first inspection pads PD1_T. For example, as illustrated in FIG. 10, first inspection pads PD1_T arranged in a first input pad row R-1 or a second input pad row R-2 in a first sub-pad area PA1-1 along the first or second direction DR1 or DR2 may be electrically connected to first through fourth resistance measurement pads RTPD1 through RTPD4 arranged in the resistance measurement pad area RTPA.

In FIGS. 9 and 10, four resistance measurement pads, i.e., the first through fourth resistance measurement pads RTPD1 through RTPD4, are illustrated. However, as depicted in FIG. 8, the resistance measurement pads RTPD may include six resistance measurement pads, i.e., the first through sixth resistance measurement pads RTPD1 through RTPD6, and each one of the three inspection pads PD_T may be electrically connected to two corresponding resistance measurement pads RTPD of the first through sixth resistance measurement pads RTPD1 through RTPD6 . The electrical connections and the arrangement structure between the resistance measurement pads RTPD and the inspection pads PD_T, within a range enabling a four-terminal resistance measurement of the contact resistances CR between the inspection pads PD_T of the display panel DP and the bumps BMP of the driving circuits DIC, are not limited to only the aforementioned aspects.

The display device 10 may be applied to various electronic devices. An electronic device according to an aspect may include the display device 10 and may further include modules or devices that provide additional functions beyond the display device 10.

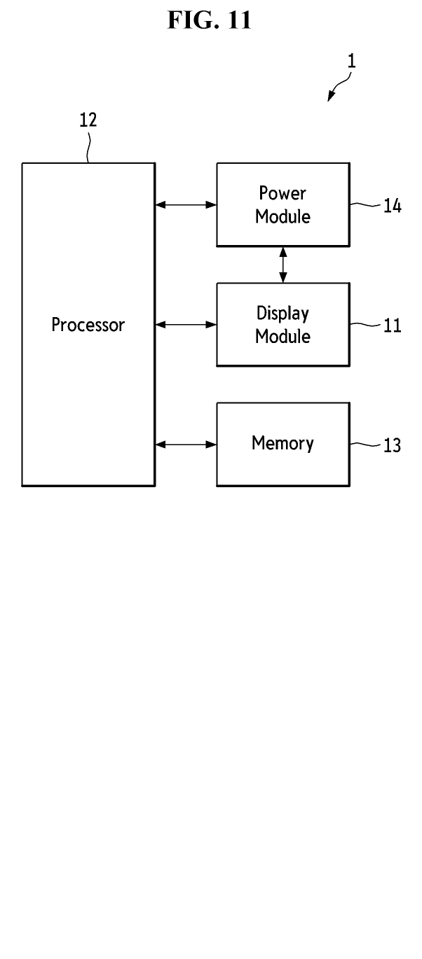

FIG. 11 is a block diagram of an electronic device according to an aspect.

Referring to FIG. 11, an electronic device 1 according to an aspect may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data and information required for the operation of the processor 12 or the display module 11. When the processor 12 executes an application stored in the memory 13, image data signals and/or input control signals may be delivered to the display module 11, and the display module 11 may process the received signals to output image information through a display screen.

The power module 14 may include a power supply module, such as a power adapter or a battery device, and a power conversion module that converts power supplied by the power supply module into power required for the operation of the electronic device 1.

At least one of the aforementioned components of the electronic device 1 may be included in a display device according to any one of the aforementioned aspects. Additionally, some of individual modules included functionally within a single module may be included in the display device, and others may be provided separately from the display device. For example, the display device may include the display module 11, while the processor 12, the memory 13, and the power module 14 may be provided as other devices included in the electronic device 1.

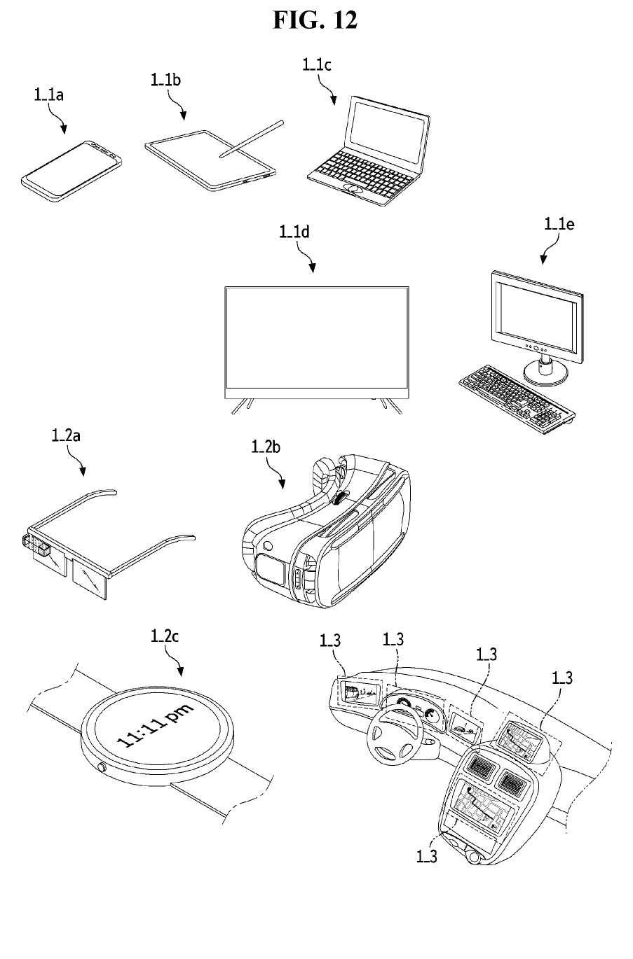

FIG. 12 illustrates schematic diagrams of electronic devices according to various aspects.

Referring to FIG. 12, various electronic devices to which the display devices according to the aspects are applied may include image display electronic devices such as a smartphone 1_1a, a tablet PC 1_1b, a laptop 1_1c, a TV 1_1d, and a desktop monitor 1_1e, wearable electronic devices that include a display module, such as smart glasses 1_2a, a head-mounted display 1_2b, and a smart watch 1_2c, and vehicle electronic devices 1_3 that include a display module, such as a center information display (CID) arranged on the instrument panel, center fascia, or dashboard of a vehicle, and a room mirror display.

In concluding the detailed description, those skilled in the art will appreciate that many variations and modifications can be made to the preferred aspects without substantially departing from the principles of the present disclosure. Therefore, the disclosed preferred aspects of the disclosure are used in a generic and descriptive sense only and not for purposes of limitation.

What is claimed is:

1. A display device comprising:
a display panel including a display area, a non-display area, and inspection pads that overlap the non-display area; and
a driving circuit positioned on the display panel, the driving circuit including inspection bumps that overlap and are electrically connected to the inspection pads of the display panel,
wherein
the display panel further includes resistance measurement pads that overlap the non-display area, but do not overlap the driving circuit, and
the resistance measurement pads are electrically connected to the inspection pads.

2. The display device of claim 1, further comprising:
conductive balls arranged between the inspection pads of the display panel and the inspection bumps of the driving circuit,
wherein the inspection pads and the inspection bumps are electrically connected by the conductive balls.

3. The display device of claim 1, wherein
the inspection pads include at least three adjacent inspection pads,
the resistance measurement pads include at least four adjacent resistance measurement pads, and
the at least four adjacent resistance measurement pads and the at least three adjacent inspection pads are electrically connected such that each of the at least three adjacent inspection pads is electrically connected to at least one of the at least four adjacent resistance measurement pads and each of the at least four adjacent resistance measurement pads is electrically connected to at least one of the at least three adjacent inspection pads.

4. The display device of claim 3, wherein the at least three adjacent inspection pads are arranged side by side in a first direction.

5. The display device of claim 3, wherein the at least three adjacent inspection pads are arranged side by side in a second direction intersecting the first direction.

6. The display device of claim 3, wherein the at least three adjacent inspection pads are arranged in both the first direction and a second direction intersecting the first direction.

7. The display device of claim 3, wherein the at least four adjacent resistance measurement pads are respectively a ground pad, a first voltage pad, a second voltage pad, and a current pad.

8. The display device of claim 1, wherein
the display panel further includes a plurality of signal pads that overlap the non-display area and are arranged in a first direction adjacent to each other and a second direction intersecting the first direction,
the driving circuit further includes a plurality of signal bumps that overlap and are electrically connected to the plurality of signal pads, respectively, and
the inspection pads are arranged adjacent to and outside of the plurality of adjacent signal pads in the first direction.

9. The display device of claim 8, further comprising:
conductive balls arranged between the plurality of signal pads of the display panel and the plurality of signal bumps of the driving circuit,
wherein the plurality of signal pads and the plurality of signal bumps are electrically connected by the conductive balls.

10. The display device of claim 8, wherein the inspection pads are electrically isolated from the plurality of signal pads.

11. The display device of claim 8, wherein
the plurality of signal pads include a plurality of first signal pads arranged along the first and second directions, and a plurality of second signal pads positioned outside the first signal pads in the second direction and arranged along the first direction, and
the plurality of first signal pads are input pads for receiving signals from the driving circuit, the plurality of second signal pads are output pads for outputting signals to the driving circuit.

12. The display device of claim 11, wherein the inspection pads include a plurality of first inspection pads positioned outside the plurality of first signal pads in the first direction, and a plurality of second inspection pads positioned outside the plurality of second signal pads in the first direction.

13. The display device of claim 12, wherein
the plurality of first inspection pads include at least three adjacent first inspection pads,
the resistance measurement pads include at least four adjacent first resistance measurement pads, and
the at least four adjacent first resistance measurement pads and the at least three adjacent first inspection pads are electrically connected such that each of the at least four adjacent first resistance measurement pads is electrically connected to at least one of the at least three adjacent first inspection pads.

14. The display device of claim 13, wherein each of the at least four adjacent first resistance measurement pads are respectively a ground pad, a first voltage pad, a second voltage pad, and a current pad.

15. The display device of claim 12, wherein
the plurality of second inspection pads include at least three adjacent second inspection pads,
the resistance measurement pads include at least four adjacent second resistance measurement pads, and
the at least four adjacent second resistance measurement pads and the at least three adjacent second inspection pads are electrically connected such that each of the at least four adjacent second resistance measurement pads is electrically connected to at least one of the at least three adjacent second inspection pads.

16. The display device of claim 15, wherein each of the at least four adjacent second resistance measurement pads are respectively a ground pad, a first voltage pad, a second voltage pad, and a current pad.

17. The display device of claim 12, wherein
the plurality of first inspection pads are arranged side by side in the first direction, and
the plurality of second inspection pads are arranged side by side in the first direction.

18. The display device of claim 12, wherein
the plurality of first inspection pads are arranged side by side in the second direction, and
the plurality of second inspection pads are arranged side by side in the first direction.

19. The display device of claim 12, wherein
the plurality of first inspection pads are arranged in the first and second directions, and
the plurality of second inspection pads are arranged side by side in the first direction.

20. An electronic device comprising:
a display device for displaying an image; and
a processor configured to transmit an image data signal to the display device to display the image,
wherein
the display device comprises: a display panel including a display area, a non-display area, inspection pads that overlap the non-display area; and a driving circuit positioned on the display panel, the driving circuit including inspection bumps that overlap and are electrically connected to the inspection pads of the display panel,
the display panel further includes resistance measurement pads that overlap the non-display area, but do not overlap the driving circuit, and
the resistance measurement pads are electrically connected to the inspection pads.
